(19) United States
(12) Patent Application Publication
(10) Pub. No.: US 2013/0215050 A1
(43) Pub. Date: Aug. 22, 2013

(54) COMPOSITE LAYER STRUCTURE AND TOUCH DISPLAY DEVICE HAVING THE SAME THEREOF

(71) Applicants: INNOCOM TECHNOLOGY(SHENZHEN)CO., LTD., (US); CHIMEI INNOLUX CORPORATION, (US)

(72) Inventor: Szu-Wei Lai, Miao-Li County (TW)

(73) Assignees: CHIMEI INNOLUX CORPORATION, Miao-Li County (TW); INNOCOM TECHNOLOGY(SHENZHEN)CO., LTD., Longhua Town (CN)

(21) Appl. No.: 13/721,140

(22) Filed: Dec. 20, 2012

(30) Foreign Application Priority Data
Feb. 17, 2012 (TW) 101105322

(51) Int. Cl. G06F 3/041; H05K 1/02

(52) U.S. Cl. CPC G06F 3/041; H05K 1/0298
USPC 345/173; 428/457; 428/336; 174/250

(57) ABSTRACT

A composite layer structure used in a touch display device is disclosed. The composite layer structure comprises a matrix material, a non-conductive metal layer and a transparent electrical-conductive layer. The non-conductive metal layer is disposed on the matrix material. The non-conductive metal layer and the transparent electrical-conductive layer are formed a stacked structure.

This application claims the benefit of Taiwan application Serial No. 101105322, filed Feb. 17, 2012, the subject matter of which is incorporated herein by reference.

### BACKGROUND

1. Field

The invention is related to a composite layer structure and a display device having the same thereof, and more particularly to an anti-etch patterns composite layer structure formed by a non-conductive metal layer and a transparent electrical-conductive layer as well as a display device having the same thereof.

2. Description of the Related Art

With the advance of science and technology, different kinds of displayer products occupied human life. Electrode structures exist in displayer products, such as a liquid crystal displayer (LCD), an organic light emitting diode displayer (OLED), an electronic books (E-book) or a touch panel displayer. Voltages can be applied to the electrode structures to form an electrical circuit. When the electrode structure is disposed within an active area (AA) of the displayer, transparent electrical-conductive materials are usually used for forming the electrode. As shown in FIG. 1A, a transparent electrical-conductive layer 12 is disposed on a substrate 10, a light transmittance and a light reflectivity of the transparent electrical-conductive layer 12 are different from a light transmittance and a light reflectivity of the substrate 10.

Therefore, when the transparent electrical-conductive layer 12 within the active area does not cover the whole scope of the substrate 10, the observer would see both the area with transparent electrical-conductive layer 12 and the area without transparent electrical-conductive layer 12 (such as an exposed substrate 10 uncovered by the transparent electrical-conductive layer 12) within the active area. In other words, the observer might observe an area with electrode structure (transparent electrical-conductive layer 12) and an area without electrode structure (substrate 10) within the active area. This phenomenon is known as and referred to as etch patterns by a person skilled in this art.

### SUMMARY

The invention is direct to a composite layer structure and a display device having the same for improving etch patterns of transparent electrical-conductive layer. By utilizing a composite layer structure formed by a non-conductive metal layer and a transparent electrical-conductive layer to replace a conventional transparent electrical-conductive layer for achieving anti-etch patterns effect. Therefore, problems of etch patterns within an active area can be solved in a display device having the composite layer structure.

According to one aspect of the invention, a composite layer structure used in a touch display device is disclosed. The composite layer structure comprises a matrix material, a non-conductive metal layer and a transparent electrical-conductive layer. The non-conductive metal layer is disposed on the matrix material. The transparent electrical-conductive layer and the non-conductive metal layer are stacked on each other.

According to another aspect of the invention, a touch display device having an active area and a non active area is disclosed. The touch display device comprises a first substrate, a first non-conductive metal layer and a first patterned transparent electrical-conductive layer. The first non-conductive metal layer is disposed on one side of the first substrate and is disposed at the active area. The first patterned transparent electrical-conductive layer and the first non-conductive metal layer are stacked on each other.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1A illustrates a diagram of a conventional transparent electrical-conductive layer disposed on a substrate.

FIG. 1B illustrates a structure of a transparent electrical-conductive layer disposed on the substrate for improving an etch patterns effect known by the inventor.

FIGS. 2A˜2B illustrate manufacturing processes of a composite layer structure according to one embodiment of the invention.

FIGS. 3A˜3B illustrate another embodiment of a composite layer structure the invention.

FIG. 4 illustrates top view of a touch display device according to still another embodiment of the invention.

FIGS. 5A˜5B illustrate cross section views of a touch display device in FIG. 4 along a cross-section line 2-2 according to one embodiment of the invention.

FIGS. 6A˜6C illustrate cross section views of a touch display device of FIG. 4 along a cross-section line 2-2 according to another embodiment of the invention.

FIGS. 7A˜7C illustrate cross section views of a touch display device of FIG. 4 along a cross-section line 2-2 according to still another embodiment of the invention.

FIG. 8 illustrates a composite layer structure applied in a touch display device according to an embodiment of the invention.

### DETAILED DESCRIPTION

First, a method for improving the effect of etch patterns know by the inventor is described below. Then, disadvantages and problems of the method are described. Finally, a composite layer structure and a display device having the same are developed for more effectively improving the effect of etch patterns is disclosed.

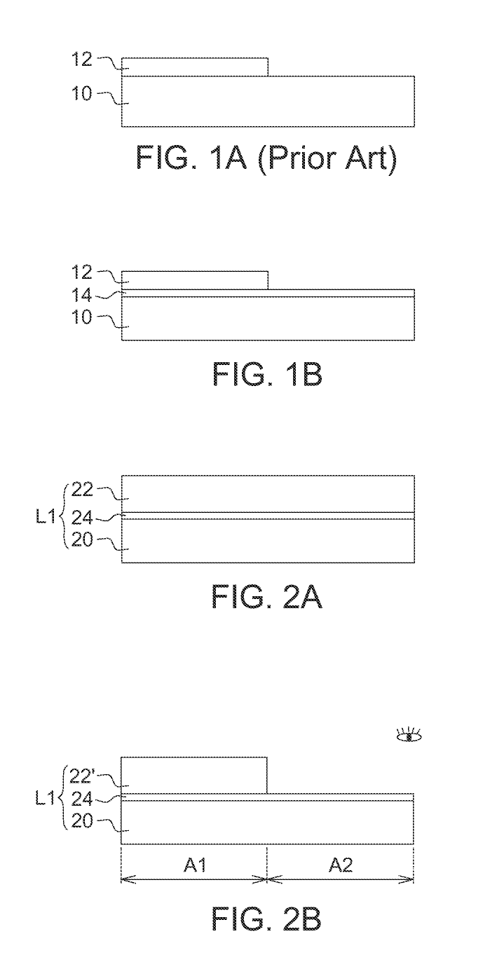

FIG. 1B illustrates a structure known by the inventor for reducing etch patterns generated because of a transparent electrical-conductive layer being disposed on a substrate. Please refer to FIG. 1B, an adjusting layer 14 is formed on a substrate 10. Then, a transparent electrical-conductive layer 12 is formed on the adjusting layer 14. By controlling the material and the thickness of the adjusting layer 14, the reflectivity of area having merely the adjusting layer 14 is similar to the reflectivity of area having the adjusting layer 14 and the transparent electrical-conductive layer 12. Therefore, the problem of conventional etch patterns can be solved.

The material of adjusting layer 14 is ceramic dielectric material or organic polymer composite material. However, the ceramic dielectric material or organic polymer composite material is inappropriate for manufacture process. For example, a reactive dry type film formation method may be used for forming an adjusting layer 14 by ceramic dielectric material. The manufacture process of reactive dry type film formation is time wasting, unstable and complexity, thereby leading to low yield rate. Besides, the ceramic dielectric material is stiff and fragile thereby unfavorable to flexible displayer. In addition, a wet type coating method may be used for forming an adjusting layer 14 by organic polymer composite material. The wet type coating process being integrated with the dry type film formation process for forming the transparent electrical-conductive layer 12 is not easy. Besides, forming an optical level smooth film is also not easily by using wet type coating process. The selection of organic polymer composite material is rare, the yielding rate of the manufacture process is disappointing and the coating equipment is expansive.

### The First Embodiment

FIGS. 2A˜2B illustrate processes for forming a composite layer structure L1. Please refer to FIG. 2A, a matrix material 20 is provided, a non-conductive metal layer 24 and a transparent electrical-conductive layer 22 are formed respectively. A thickness of the non-conductive metal layer 24 is less than 10 nm, a material for forming the non-conductive metal layer 24 is selected from a group consisting of indium (In), tin (Sn), indium tin alloy, indium alloy, tin alloy, tantalum (Ta) or other non-conductive metal materials with a sheet resistance larger than 10⁶ ohm/square (Ω/sq). Since the non-conductive metal layer 24 has a high resistance, the non-conductive metal layer 24 has little effect on transparent electrical-conductive layer 22 for electric signal transmission. Besides, problems of short circuits are also avoided.

In this embodiment, a non-conductive metal layer 24, for example, can be formed by techniques of non conductive vacuum metalization (NCVM), which is one type of the dry type film formation. The transparent electrical-conductive layer 22, for example, can be formed on the non-conductive metal layer 24 with indium tin oxide (ITO), indium zinc oxide (IZO) or zinc oxide (ZnO) by dry type film formation. The dry type film formation process can be physical evaporation or chemical evaporation. For example, chemical evaporation can be plasma-enhanced chemical vapor deposition (PECVD), low pressure chemical vapor deposition (LPCVD) or polymer polymerization chemical vapor deposition (PPCVD).

Please refer to FIG. 2B, the transparent electrical-conductive layer 22 is patterned by lithography manufacture process to form patterned transparent electrical-conductive layer 22′. As shown in FIG. 2B, a composite layer structure L1 comprises a matrix material 20, a patterned transparent electrical-conductive layer 22′ and a non-conductive metal layer 24. The composite layer structure L1 comprises the first area A1 and the second area A2. When the observer observes the composite layer structure L1 at the side of the composite layer structure L1 toward the matrix material 20, the observer observes the patterned transparent electrical-conductive layer 22′ at the first area A1, and observes the non-conductive metal layer 24 at the second area A2.

In the first area A1, the composite structure of the patterned transparent electrical-conductive layer 22′ and non-conductive metal layer 24 has a first light transmittance and a first light reflectivity. In the second area A2, the non-conductive metal layer 24 has a second light transmittance and a second light reflectivity. An indium material made non-conductive metal layer 24 is taken as an example. The thicknesses of the non-conductive metal layer 24, the differences between the first and the second light reflectivity, and the differences between the first and the second light transmittance are shown in Table 1.

TABLE 1

| Thicknesses of | Differences between | Differences between |
|---|---|---|
| indium material made | the first and the | the first and the |
| non-conductive metal layer | second light | second light |
| 24 (nm) | reflectivity | transmittance |
| 0 | 2.02 | −2.74 |
| 1 | 0.65 | −1.28 |
| 1.5 | −0.03 | −0.61 |
| 2 | −0.68 | 0.01 |

Please refer to both FIG. 2B and Table 1, when the non-conductive metal layer 24 not exist (the thickness of non-conductive metal layer 24 equals to 0), the absolute value of difference between the first light reflectivity and the second light reflectivity as well as the absolute value of differences between the first and the second light transmittance are larger than 2. After forming non-conductive metal layer 24 with thickness of 1 nm, 1.5 nm or 2 nm between the matrix material 20 and the patterned transparent electrical-conductive layer 22′ respectively, the differences between the first and the second light reflectivity as well as the differences between the first and the second light transmittance are obviously reduced. That is to say, the value of the first light transmittance is close to the value of the second light transmittance, and the value of the first light reflectivity is close to the second light reflectivity. Therefore, human eyes can not differentiate the non-conductive metal layer 24 and the patterned transparent electrical-conductive layer 22′.

Particularly, Table 1 merely shows the experiment results of non-conductive metal layer 24 with thicknesses of 1 nm, 1.5 nm and 2 nm. In fact, as long as the thickness of non-conductive metal layer 24 is substantially less than 10 nm, the etch patterns effect can be reduced. Considering the tolerances of manufacture process, the range of thickness covers the errors comprehended by a person skilled in the art.

### The Second Embodiment

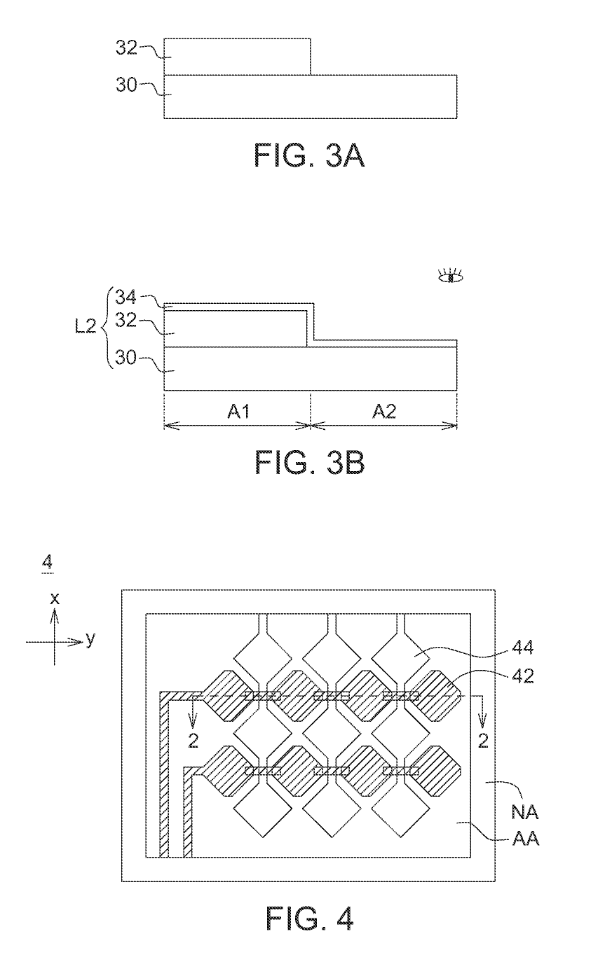

FIGS. 3A˜3B illustrate processes for forming composite layer structure L2. Please refer to FIG. 3A, a matrix material 30 is provided. A patterned transparent electrical-conductive layer 32 is formed on the matrix material 30. Referring to FIG. 3B, then, a non-conductive metal layer 34 is formed on the patterned transparent electrical-conductive layer 32 and the matrix material 30. The thickness of the non-conductive metal layer 34 is smaller than 10 nm. The materials and forming methods of the non-conductive metal layer 34 and the non-conductive metal layer 24 are the same as that in the first embodiment. Therefore, the electric signal of the transmission of the patterned transparent electrical-conductive layer 32 would not be effected. Besides, the short circuit problem can be avoided. Besides, the material and forming method of the patterned transparent electrical-conductive layer 32 are the same as that of the transparent electrical-conductive layer 22 in the first embodiment. The difference between the two embodiments is that, in this embodiment, the patterned transparent electrical-conductive layer 32 is formed on the matrix material 30 first. Then, the non-conductive metal layer 34 covers the patterned transparent electrical-conductive layer 32 and the matrix material 30.

Please refer to FIG. 3B, the composite layer structure L2 comprises the matrix material 30, the patterned transparent electrical-conductive layer 32 and the non-conductive metal layer 34. Besides, the composite layer structure L2 can comprise the first area A1 and the second area A2. When the observer observes the composite layer structure L2 at the side having the composite layer structure L2 toward the matrix material 30, the observer observes the non-conductive metal layer 34 at both the first area A1 and the second area A2. In the first area A1, the non-conductive metal layer 34 and the patterned transparent electrical-conductive layer 32 have a third light transmittance and a third light reflectivity. In the second area A2, the non-conductive metal layer 34 has a fourth light transmittance and a fourth light reflectivity. In this embodiment, a thickness of the indium material made non-conductive metal layer 34, the differences between the third and the fourth light reflectivity as well as the third and the fourth light transmittance are shown in Table 2.

TABLE 2

| | Differences | Differences |
|---|---|---|
| Thicknesses of indium material | between the third | between the third |
| made non-conductive | and the fourth | and the fourth |
| metal layer 34 (nm) | light reflectivity | light transmittance |
| 0 | 1.94 | −2.64 |
| 1 | 1.63 | −2.01 |
| 2 | 1.35 | −1.46 |
| 4 | 0.87 | −0.55 |

Please refer to FIG. 3B and Table 2, when the non-conductive metal layer 34 not exist (the thickness of non-conductive metal layer 34 equals to 0), the absolute value of difference between the third and the fourth light reflectivity is close to 2. Besides, the absolute value of difference between the third and the fourth light transmittance is larger than 2. After forming non-conductive metal layer 34 with thickness of 1 nm, 2 nm or 4 nm on the matrix material 30 and the patterned transparent electrical-conductive layer 32, the differences between third and the fourth light reflectivity and the differences between the third and the fourth light transmittance are obviously reduced. That is to say, the value of the third light transmittance is close to the value of the fourth light transmittance, and the value of the third light reflectivity is close to the fourth light reflectivity. Therefore, human eyes can not differentiate the non-conductive metal layer 34 and the patterned transparent electrical-conductive layer 32.

Particularly, Table 2 merely shows the experiment results of non-conductive metal layer 34 with thicknesses of 1 nm, 2 nm and 4 nm. In fact, as long as the thickness of non-conductive metal layer 34 is substantially less than 10 nm, the etch patterns effect can be reduced. Considering the tolerances of manufacture process, the range of thickness covers the errors comprehended by a person skilled in the art.

Applying the Above Embodiments to Form the Composite Layer Structure in a Display Device

FIG. 4 illustrates a top view of a composite layer structure applying in a touch display device 4 according to one embodiment of the invention. Please refer to FIG. 4, a metal layer and an insulating layer of the touch display device 4 are omitted, and merely a stacked structure of the electrodes 42 and the electrodes 44 within the active area AA of the touch display device 4 are illustrated to simplify the description.

Please refer to FIG. 4, a touch display device 4 has an active area AA and a non-active area NA. The active area AA has a patterned transparent electrical-conductive layer structure with two different aligning directions, for example, a plurality of electrodes 42 and a plurality of electrodes 44 can be formed with indium tin oxide, indium-zinc oxide or zinc oxide by utilizing dry type film formation method. The electrodes 44 are aligned in x direction and the electrodes 42 are aligned in y direction, and the electrodes 42 and the electrodes 44 are electrical insulated.

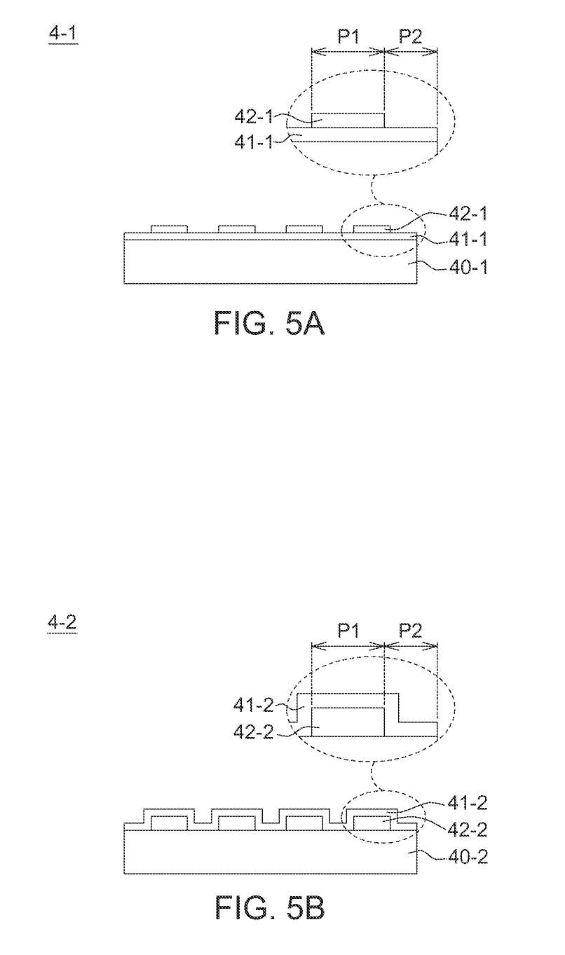

FIGS. 5A˜5B illustrate cross section views of a touch display device 4-1. The touch display device 4-1 is a cross section view along a cross-section line 2-2 of touch display device 4 in FIG. 4. Please refer to FIG. 5A, the touch display device 4-1 comprises a first substrate 40-1, a non-conductive metal layer 41-1 and electrodes 42-1. In this embodiment, the first substrate 40-1 can be a plastic substrate formed by polyethylene terephthalate (PET) for example. The electrodes 42-1 can be one embodying type of the electrodes 42 in FIG. 4. The first substrate 40-1, the non-conductive metal layer 41-1 and the electrodes 42-1 can be disposed on the active area AA of the first substrate 40-1 by ways of the disposition of the composite layer structure L1 (shown in FIG. 3A) in the first embodiment. In this embodiment, the active area AA (shown in FIG. 4) further comprises the first area P1 and the second area P2 adjacent to the first area P1. The non-conductive metal layer 41-1 and the electrodes 42-1 correspond to the first area P1, and the electrodes 42-1 and the non-conductive metal layer 41-1 are stacked in the first area P1. Besides, a single structure of the non-conductive metal layer 41-1 corresponds to the second area P2.

Please refer to FIG. 5B, elements of a touch display device 4-2 are the same as the corresponding elements in touch display device 4-1 of FIG. 5A. The difference between the touch display device 4-1 and the touch display device 4-2 is that the first substrate 40-2, the non-conductive metal layer 41-2 and the electrodes 42-2 of the touch display device 4-2 are disposed by ways of the disposition of the composite layer structure L2 (shown in FIG. 3B) in the second embodiment. In this embodiment, the electrodes 42-2 can be another embodying type of the electrodes 42 in FIG. 4. The active area AA (shown in FIG. 4) comprises the first area P1 and the second area P2. The non-conductive metal layer 41-2 and the electrodes 42-2 correspond to the first area P1, the electrodes 42-2 and the non-conductive metal layer 41-2 are stacked in the first area P1. Besides, a single structure of the non-conductive metal layer 41-2 corresponds to the second area P2.

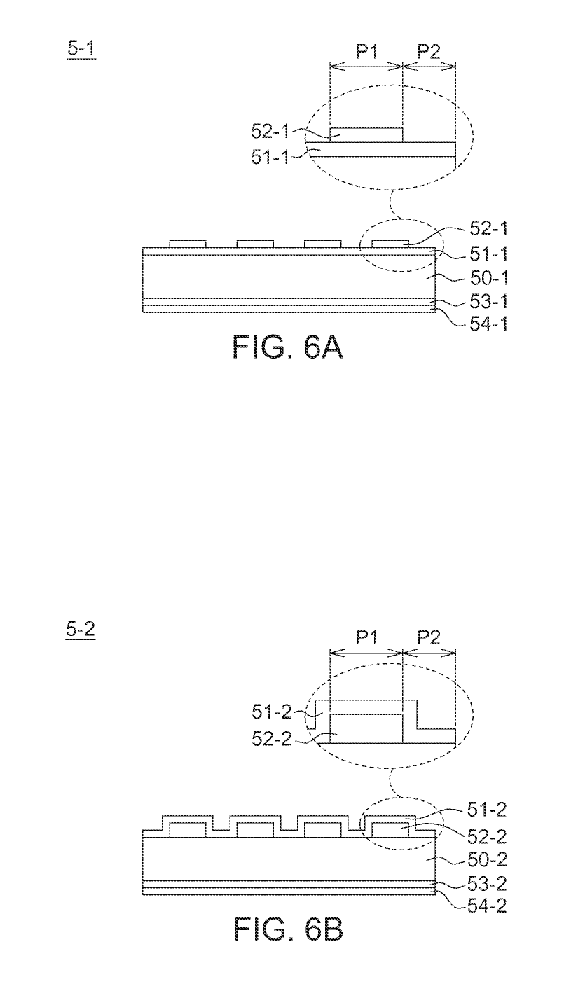

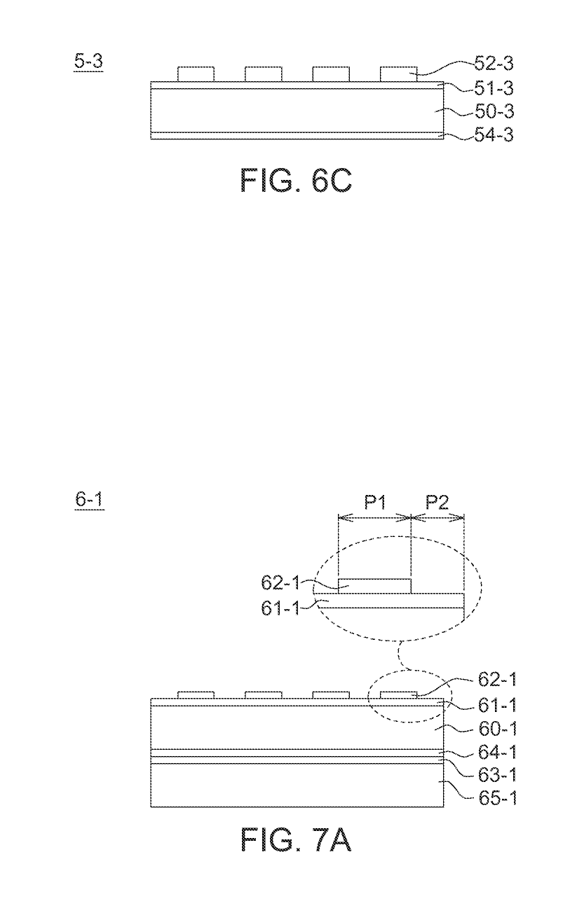

FIGS. 6A˜6C illustrate cross section views of a touch display device 4 along a cross-section line 2-2. Referring to FIG. 6A, the touch display device 5-1 comprises a first substrate 50-1, a non-conductive metal layer 51-1, electrodes 52-1, a non-conductive metal layer 53-1 and electrodes 54-1.

As shown in FIG. 6A, electrodes 52-1 and a non-conductive metal layer 51-1 of a touch display device 5-1 is disposed on one side of the first substrate 50-1 by ways of the disposition of the composite layer structure L1 without the matrix material in the first embodiment. The electrodes 54-1 and the non-conductive metal layer 53-1 can be selected from, but not limited to, the composite layer structure L1 without the matrix material in the first embodiment or the composite layer structure L2 without the matrix material in the second embodiment, and the electrodes 54-1 and the non-conductive metal layer 53-1 can be disposed on another side of the first substrate 50-1. The non-conductive metal layer 51-1 and the electrodes 52-1 correspond to the first area P1. The electrodes 52-1 and the non-conductive metal layer 51-1 are stacked to each other within the first area P1. Besides, the single structure of the non-conductive metal layer 51-1 corresponds to the second area P2.

Please refer to FIG. 6B, the touch display device 5-2 comprises a substrate 50-2, a non-conductive metal layer non-conductive metal 51-2, electrodes 52-2, a non-conductive metal layer 53-2 and electrodes 54-2. The elements of touch display device 5-2 are the same as the corresponding elements of touch display device 5-1, the differences between the touch display device 5-2 are that the electrodes 52-2 and the non-conductive metal layer 51-2 are disposed on one side of the substrate 50-2 by ways of the disposition of the composite layer structure L2 without the matrix material in the second embodiment. The electrodes 54-2 and the non-conductive metal layer 53-2 can be selected from, but not limited to, the composite layer structure L1 without the matrix material in the first embodiment or the composite layer structure L2 without the matrix material in the second embodiment, and disposed on another side of the first substrate 50-2. The non-conductive metal layer 51-2 and the electrodes 52-2 correspond to the first area P1. The electrodes 52-2 and the non-conductive metal layer 51-2 stacked on each other within the first area P1. Besides, the single structure of the non-conductive metal layer 51-2 corresponds to the second area P2.

In particular, FIGS. 6A˜6B illustrate that the non-conductive metal layer 53-1 is disposed between the electrodes 54-1 and the first substrate 50-1, and the non-conductive metal layer 53-2 is disposed between the electrodes 54-2 and the first substrate 50-2. However, the electrodes 54-1 can also be disposed between, but not limited to, the non-conductive metal layer 53-1 and the first substrate 50-1, and the electrodes 54-2 can be disposed between, but not limited to, the non-conductive metal layer 53-2 and the first substrate 50-2.

Please refer to FIG. 6C, the touch display device 5-3 comprises a first substrate 50-3, a non-conductive metal layer 51-3, electrodes 52-3 and electrodes 54-3. The elements of the touch display device 5-3 are the same as the corresponding elements of the touch display device 5-1. The differences between the touch display device 5-1 and the touch display device 5-3 is that the electrodes 54-3 in touch display device 5-3 lacks of a stacked non-conductive metal layer.

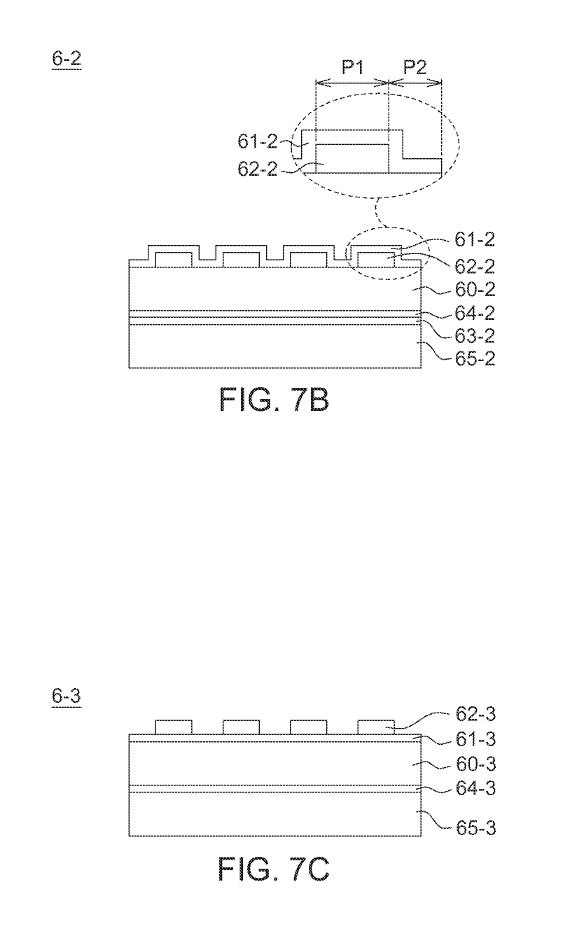

FIGS. 7A˜7C illustrate other cross section views of the touch display device 4 along the cross-section line 2-2 in FIG. 4. Please refer to FIG. 7A, the touch display device 6-1 comprises a first substrate 60-1, a non-conductive metal layer 61-1, electrodes 62-1, electrodes 64-1, a non-conductive metal layer 63-1 and a second substrate 65-1. In this embodiment, the non-conductive metal layer 61-1 and the electrodes 62-1 are disposed on the substrate 60-1 by ways of the structure subtract the matrix material in the first embodiment. The non-conductive metal layer 63-1 and the electrodes 64-1 can be disposed on the second substrate 65-1 by ways of the structure without the matrix material in the first embodiment or the structure without the matrix material in the second embodiment. The non-conductive metal layer 61-1 and the electrodes 62-1 correspond to the first area P1, the first area P1 the electrodes 62-1 and the non-conductive metal layer 61-1 stacked on each other. Besides, the single structure of the non-conductive metal layer 61-1 corresponds to the second area P2.

Please refer to FIG. 7B, the touch display device 6-2 comprises a first substrate 60-2, a non-conductive metal layer 61-2, electrodes 62-2, electrodes 64-2, a non-conductive metal layer 63-2 and a second substrate 65-2. In this embodiment, the non-conductive metal layer 61-2 and the electrodes 62-2 disposed on one side of the first substrate 60-2 by ways of the second embodiment without the matrix material. The non-conductive metal layer 63-2 and the electrodes 64-2 can be disposed on the second substrate 65-2 by ways of the disposition in the first embodiment or in the second embodiment without a matrix material. The non-conductive metal layer 61-2 and the electrodes 62-2 correspond to the first area P1. The electrodes 62-2 and the non-conductive metal layer 61-2 stacked on each other within the first area P1. The single structure of the non-conductive metal layer 61-2 correspond to the second area P2.

In particular, the non-conductive metal layer 63-1 is disposed between the electrodes 64-1 and the substrate 65-1 in FIGS. 7A˜7B. The non-conductive metal layer 63-2 is disposed between the electrodes 64-2 and the second substrate 65-2. The electrodes 64-1 can also be disposed between, but not limited to, the non-conductive metal layer 63-1 and the second substrate 65-1 according to the manufacture process or design requirement. Besides, the electrodes 64-2 can also be disposed between, but not limited to, the non-conductive metal layer 63-2 and the second substrate 65-2 according to the manufacture process or design requirement.

Please refer to FIG. 7C, the touch display device 6-3, comprises a first substrate 60-3, a second substrate 65-3, a non-conductive metal layer 61-3, electrodes 62-3 and electrodes 64-3. The elements of touch display device 6-3 are similar to the corresponding elements of the touch display device 6-1 and the touch display device 6-2, and the difference is that the electrodes 64-3 of the touch display device 6-3 lacks of a stacked non-conductive metal layer.

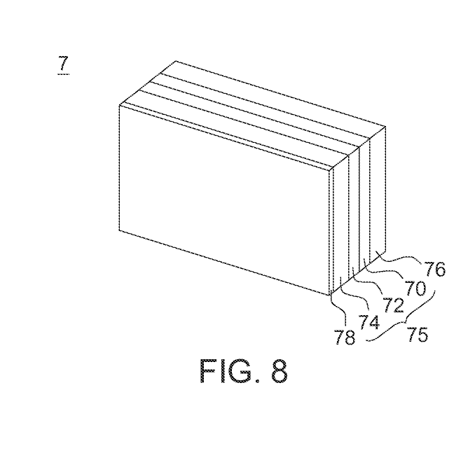

FIG. 8 illustrates a composite layer structure applied in a touch display device 7 according to an embodiment of the invention. Please refer to FIG. 8, a touch display device 7 comprises a touch panel 75, a display panel 76 and a cover 78. The touch panel 75 comprises a first substrate 70, a non-conductive metal layer 72 and a patterned transparent electrical-conductive layer 74. The display panel 76 is for example a liquid crystal panel, a organic light emitting diode (OLED) panel or a light emitting diode panel. In this embodiment, the non-conductive metal layer 72 and the patterned transparent electrical-conductive layer 74 of the touch panel 75 is, for example, disposed on the first substrate 70 by ways of the disposition the composite layer structure L1 without the matrix material in the first embodiment or the composite layer structure L2 without the matrix material in the second embodiment of the invention.

Based on the above, the composite layer structure in the embodiments of the invention have advantages as follows:

1. The conventional transparent electrical-conductive layer is replaced by a composite layer structure formed of the non-conductive metal layer and the transparent electrical-conductive layer to achieve the anti-etch patterns effect, so that the etch patterns problem within the active area of the display device with the composite layer structure can be improved.

2. The manufacture process of the non-conductive metal layer is stable and simple. Films can be formed by vapor deposition or sputtering techniques. The vapor deposition or sputtering techniques can form nanometer-leveled non-conductive metal films uniformly and smoothly in a short time. Besides, the non-conductive metal material used for forming the non-conductive metal layer has good malleability and flexibility.

3. The non-conductive metal material is formed adjacent to the transparent electrical-conductive layer. The resistance of the non-conductive metal material is high so that the short circuit phenomenon can be avoided.

4. The non-conductive metal layer and the transparent electrical-conductive layer can be formed by dry type film formation technique, so that the manufacture processes of the non-conductive metal layer and the transparent electrical-conductive layer can be integrated, the yielding rate can be improved and the time of the manufacture process can be reduced.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A composite layer structure used in a touch display device, the composite layer structure comprising:
a matrix material;
a non-conductive metal layer disposed on the matrix material; and
a transparent electrical-conductive layer, the transparent electrical-conductive layer and the non-conductive metal layer staked on each other.

2. The composite layer structure according to claim 1, wherein the transparent electrical-conductive layer is a patterned transparent electrical-conductive layer.

3. The composite layer structure according to claim 2, wherein an area of the non-conductive metal layer is larger than an area of the patterned transparent electrical-conductive layer.

4. The composite layer structure according to claim 2, wherein the composite layer structure comprises a first area and a second area, the first area has the non-conductive metal layer and the patterned transparent electrical-conductive layer, the second area has the non-conductive metal layer.

5. The composite layer structure according to claim 4, wherein the first area has a first light transmittance and a first light reflectivity, the second area has a second light transmittance and a second light reflectivity, a difference between the first light transmittance and the second light transmittance is smaller than 2.01, a difference between the first light reflectivity and the second light reflectivity is smaller than 1.63.

6. The composite layer structure according to claim 1, wherein a sheet resistance of a material for forming the non-conductive metal layer is larger than 10⁶ ohm/square (Ω/sq).

7. The composite layer structure according to claim 1, wherein a material for forming the non-conductive metal layer is selected from a group consisting of indium (In), tin (Sn), indium tin alloy, indium alloy, tin alloy and tantalum (Ta).

8. The composite layer structure according to claim 1, wherein a thickness of the non-conductive metal layer is less than 10 nm.

9. A touch display device comprising a active area and a non-active area, the touch display device comprising:
a first substrate;
a first non-conductive metal layer disposed on one side of the first substrate at the active area; and
a first patterned transparent electrical-conductive layer, the first patterned transparent electrical-conductive layer and the first non-conductive metal layer stacked on each other.

10. The display device according to claim 9, wherein the first patterned transparent electrical-conductive layer comprises a plurality of first electrodes aligned in a first direction.

11. The display device according to claim 10, further comprising a second patterned transparent electrical-conductive layer disposed on the active area, wherein the second patterned transparent electrical-conductive layer comprises a plurality of second electrodes, the second electrodes are aligned in a second direction, the first direction and the second direction are different.

12. The display device according to claim 11, further comprising a second non-conductive metal layer, wherein the second non-conductive metal layer and the second patterned transparent electrical-conductive layer are stacked on each other.

13. The display device according to claim 11, wherein the second patterned transparent electrical-conductive layer is disposed on another side of the first substrate.

14. The display device according to claim 11, further comprising a second substrate opposite to the first substrate, wherein the second patterned transparent electrical-conductive layer is disposed on a side of the second substrate.

15. The display device according to claim 14, further comprising a second non-conductive metal layer, wherein the second non-conductive metal layer is disposed between the second substrate and the second patterned transparent electrical-conductive layer.

16. The display device according to claim 9, wherein the first non-conductive metal layer is disposed between the first substrate and the first patterned transparent electrical-conductive layer.

17. The display device according to claim 9, wherein a sheet resistance of a material of the non-conductive metal layer is larger than 10⁶ ohm/square (Ω/sq).

18. The display device according to claim 9, wherein a thickness of the non-conductive metal layer is less than 10 nm.

19. The display device according to claim 9, wherein the active area comprises a first area and a second area, the first area has the first non-conductive metal layer and the first patterned transparent electrical-conductive layer, the first patterned transparent electrical-conductive layer and the first non-conductive metal layer are stacked on each other, the second area has the first non-conductive metal layer.

20. The display device according to claim 19, wherein the first area has a first light transmittance and a first light reflectivity, the second area has a second light transmittance and a second light reflectivity, a difference between the first light transmittance and the second light transmittance is less than 2.01, a difference between the first light reflectivity and the second light reflectivity is less than 1.63.
